(19) United States
(12) Patent Application Publication
(10) Pub. No.: US 2025/0248037 A1
(43) Pub. Date: Jul. 31, 2025

(54) MEMORY DEVICE AND METHOD OF MANUFACTURING THE SAME

(71) Applicant: SK hynix Inc., Icheon-si Gyeonggi-do (KR)

(72) Inventors: Sang Hyun HAN, Icheon-si Gyeonggi-do (KR); Jae Seok KIM, Icheon-si Gyeonggi-do (KR); Hwae Bong JUNG, Icheon-si Gyeonggi-do (KR); Bo Ram PARK, Icheon-si Gyeonggi-do (KR)

(73) Assignee: SK hynix Inc., Icheon-si Gyeonggi-do (KR)

(21) Appl. No.: 18/743,682

(22) Filed: Jun. 14, 2024

(30) Foreign Application Priority Data
Jan. 25, 2024 (KR) 10-2024-0011478

(51) Int. Cl. H10B 43/27; H10B 43/40

(52) U.S. Cl. CPC H10B 43/27; H10B 43/40

(57) ABSTRACT

A memory device includes a cell area and a contact area extending from the cell area in a first direction. The contact area includes a stepped structure arranged along a second direction that intersects the first direction. The memory device also includes a support pattern separating the contact area into a first contact area coupled to the cell area and a second contact area separated from the cell area by the support pattern. The support pattern may include sub-support patterns extending in the first direction and contacting both sides of the second contact area. At least one of the sub-support patterns overlaps at least a portion of the stepped structure, and the second contact area does not overlap with the stepped structure.

### CROSS-REFERENCE TO RELATED APPLICATION

The present application claims priority under 35 U.S.C. § 119(a) to Korean patent application number 10-2024-0011478 filed on Jan. 25, 2024, in the Korean Intellectual Property Office, the entire disclosure of which application is incorporated by reference herein.

### BACKGROUND

### 1. Technical Field

Various embodiments of the present disclosure generally relate to a memory device and a method of manufacturing the memory device, and more particularly, to a memory device including a three-dimensional memory block and a method of manufacturing the memory device including the three-dimensional memory block.

### 2. Related Art

A memory device may include a non-volatile memory device in which stored data remains intact even if its power supply is cut off. A non-volatile memory device may be classified as a two-dimensional (2D) structure or a three-dimensional (3D) structure depending on a structure in which memory cells are arranged. Memory cells of a non-volatile memory device with the 2D structure may be arranged in a single layer on a substrate, and memory cells of a non-volatile memory device with the 3D structure may be vertically stacked on a substrate. Because the integration degree of the non-volatile memory device with the 3D structure is higher than that of the non-volatile memory device with the 2D structure, the number of electronic devices using the non-volatile memory device with the 3D structure is currently increasing.

### SUMMARY

According to an embodiment of the present disclosure, a memory device may include a cell area and a contact area extending from the cell area in a first direction. The contact area may include a stepped structure arranged along a second direction that intersects the first The memory device may also include a support pattern direction. separating the contact area into a first contact area coupled to the cell area and a second contact area separated from the cell area by the support pattern. The support pattern may include sub-support patterns extending in the first direction and contacting both sides of the second contact area. At least one of the sub-support patterns may overlap at least a portion of the stepped structure, and the second contact area might not overlap with the stepped structure.

According to an embodiment of the present disclosure, a method of manufacturing a memory device may include forming a preliminary stacked body including alternately stacked first and second material layers, forming cell plugs in a cell area of the preliminary stacked body, and forming a stepped structure arranged along a second direction, which intersects a first direction, in a contact area extending from the cell area in the first direction. The method may also include forming a support pattern penetrating the contact area including sub-support patterns each extending in the first direction, the support pattern separating the contact area into a first contact area and a second contact area enclosed by the support pattern. In forming the support pattern, at least one of the sub-support patterns may overlap at least a portion of the stepped structure, and the second contact area might not overlap with the stepped structure.

### BRIEF DESCRIPTION OF THE DRAWINGS

FIG. 1 is a diagram illustrating a memory device according to an embodiment of the present disclosure.

FIG. 2 is a diagram illustrating a memory device according to an embodiment of the present disclosure.

FIGS. 3A to 3C are diagrams illustrating a cell area and a contact area according to an embodiment of the present disclosure.

FIGS. 4A and 4B are diagrams illustrating a support pattern that overlaps a stepped structure according to a first embodiment of the present disclosure.

FIGS. 5A and 5B are diagrams illustrating a support pattern that overlaps a stepped structure according to a second embodiment of the present disclosure.

FIGS. 6A to 6E are diagrams illustrating a method of manufacturing a memory device according to an embodiment of the present disclosure.

FIG. 7 is a diagram illustrating a memory card system to which a memory device according to the present disclosure is applied.

FIG. 8 is a diagram illustrating a solid-state drive (SSD) system to which a memory device according to the present disclosure is applied.

### DETAILED DESCRIPTION

Specific structural or functional descriptions in the embodiments of the present disclosure introduced in this specification or application are provided as examples to describe embodiments according to the concept of the present disclosure. The embodiments according to the concept of the present disclosure may be practiced in various forms and should not be construed as being limited to the embodiments described in the specification or application.

Various embodiments of the present disclosure are described in detail with reference to the accompanying drawings so that those skilled in the art can practice the technical spirit of the present disclosure. Some embodiments of the present disclosure are directed to a memory device and a method of manufacturing the memory device, which can improve the structural stability of a stacked body.

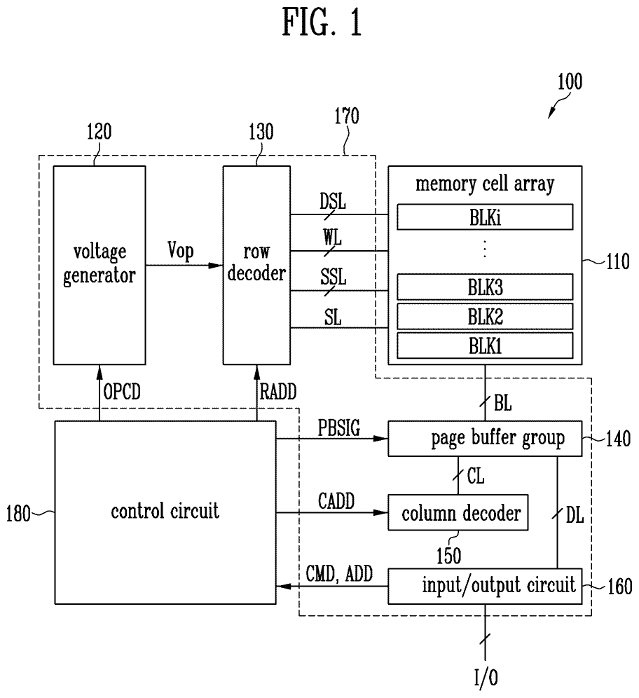

FIG. 1 is a diagram illustrating a memory device according to an embodiment of the present disclosure.

Referring to FIG. 1, a memory device 100 may include a memory cell array 110, a peripheral circuit 170, and a control circuit 180.

The memory cell array 110 may include first to i-th memory blocks BLK1 to BLKi. Each of the first to i-th memory blocks BLK1 to BLKi may include a plurality of memory cells capable of storing data. Drain select lines DSL, word lines WL, source select lines SSL, and a source line SL may be coupled to each of the first to i-th memory blocks BLK1 to BLKi, and bit lines BL may be coupled in common to the first to i-th memory blocks BLK1 to BLKi.

Each of the first to i-th memory blocks BLK1 to BLKi may have a three-dimensional (3D) structure. Each memory block having a 3D structure may include memory cells stacked in a direction vertical or normal to a substrate.

According to a program scheme, each memory cell may store 1 bit of data or 2 or more bits of data. For example, a scheme for storing 1 bit of data in one memory cell is referred to as a single-level cell (SLC) scheme, and a scheme for storing 2 bits of data in one memory cell is referred to as a multi-level cell (MLC) scheme. A scheme for storing 3 bits of data in one memory cell is referred to as a triple-level cell (TLC) scheme, and a scheme for storing 4 bits of data in one memory cell is referred to as a quad-level cell (QLC) scheme. In addition, 5 or more bits of data may be stored in one memory cell.

The peripheral circuit 170 may perform a program operation of storing data in the memory cell array 110, a read operation of outputting data stored in the memory cell array 110, and an erase operation of erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop required for a program operation, a read operation, or an erase operation in response to an operation code OPCD. For example, the voltage generator 120 may generate program voltages, turn-on voltages, turn-off voltages, negative voltages, precharge voltages, verify voltages, read voltages, pass voltages, and/or erase voltages in response to the operation code OPCD. The operating voltages Vop generated by the voltage generator 120 may be applied to the drain select lines DSL, the word lines WL, the source select lines SSL, and the source line SL of a selected memory block through the row decoder 130.

The program voltages may be voltages that are applied to a selected word line among the word lines WL during a program operation and may be used to increase the threshold voltages of memory cells coupled to the selected word line. The turn-on voltages may be applied to the drain select lines DSL or the source select lines SSL and may be used to turn on drain select transistors or source select transistors. The turn-off voltages may be applied to the drain select lines DSL or the source select lines SSL and may be used to turn off drain select transistors or source select transistors. For example, the turn-off voltage may be set to 0 V. The precharge voltages are voltages higher than 0 V and may be applied to the bit lines during a read operation. The verify voltages may be used for a verify operation of determining whether the threshold voltages of the selected memory cells have increased up to target levels. The verify voltages may be set to various levels depending on the target levels and may be applied to the selected word line.

The read voltages may be applied to the selected word line during a read operation on the selected memory cells. For example, the read voltages may be set to various levels according to the program scheme of the selected memory cells. The pass voltages may be voltages that are applied to unselected word lines, among the word lines WL, during a program operation or a read operation, and may be used to turn on memory cells coupled to the unselected word lines. The erase voltages may be used for an erase operation of erasing the memory cells included in the selected memory block, and may be applied to the source line SL.

The row decoder 130 may transfer the operating voltages Vop to the drain select lines DSL, the word lines WL, the source select lines SSL, and the source line SL, which are coupled to a memory block selected in response to a row address RADD. For example, the row decoder 130 may be coupled to the voltage generator 120 through global lines, and the row decoder 130 may be coupled to the first to i-th memory blocks BLK1 to BLKi through the drain select lines DSL, the word lines WL, the source select lines SSL, and the source line SL.

The page buffer group 140 may include page buffers (not illustrated) coupled to the first to i-th memory blocks BLK1 to BLKi, respectively. For example, respective page buffers may be coupled to the first to i-th memory blocks BLK1 to BLKi through bit lines BL. During a read operation, the page buffers may sense currents or voltages of the bit lines that vary depending on the threshold voltages of selected memory cells in response to page buffer control signals PBSIG, and the page buffers may temporarily store sensed data.

The column decoder 150 may be configured such that data is transferred between the page buffer group 140 and the input/output circuit 160 in response to a column address CADD. For example, the column decoder 150 may be coupled to the page buffer group 140 through column lines CL and may transmit enable signals through the column lines CL. The page buffers (not illustrated) included in the page buffer group 140 may receive or output data through data lines DL in response to the enable signals.

The input/output circuit 160 may receive or output a command CMD, an address ADD, or data through input/output lines I/O. For example, the input/output circuit 160 may transmit a command CMD and an address ADD, received from an external controller through the input/output lines I/O, to the control circuit 180, and may transmit the data, received from the external controller through the input/output lines I/O, to the page buffer group 140. Alternatively, the input/output circuit 160 may output data received from the page buffer group 140 to the external controller through the input/output lines I/O.

The control circuit 180 may output at least one of the operation code OPCD, the row address RADD, the page buffer control signals PBSIG, or the column address CADD in response to a command CMD and an address ADD. For example, when the command CMD input to the control circuit 180 is a command corresponding to a program operation, the control circuit 180 may control the peripheral circuit 170 so that a program operation is performed on a memory block selected by the address ADD. When the command CMD input to the control circuit 180 is a command corresponding to a read operation, the control circuit 180 may control the peripheral circuit 170 so that a read operation is performed on a memory block selected by the address and read data is output. When the command CMD input to the control circuit 180 is a command corresponding to an erase operation, the control circuit 180 may control the peripheral circuit 170 so that an erase operation is performed on a selected memory block.

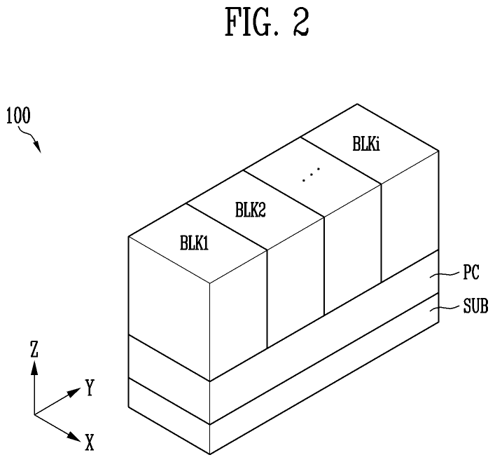

FIG. 2 is a diagram illustrating a memory device according to an embodiment of the present disclosure.

Referring to FIG. 2, the memory device 100 may include a peripheral circuit structure PC disposed on a substrate SUB and memory blocks BLK1 to BLKi. The memory blocks BLK1 to BLKi may overlap the peripheral circuit structure PC.

The substrate SUB may be a single crystal semiconductor layer. For example, the substrate SUB may be a bulk silicon substrate, a silicon-on-insulator substrate, a germanium substrate, a germanium-on-insulator substrate, a silicon-germanium substrate, or an epitaxial thin film formed through a selective epitaxial growth method.

The peripheral circuit structure PC may include a row decoder 130, a column decoder 150, a page buffer group 140, a control circuit 180, etc., which constitute a circuit for controlling the operation of the memory blocks BLK1 to BLKi. For example, the peripheral circuit structure PC may include NMOS transistors, PMOS transistors, resistors, capacitors, etc., which are electrically connected to the memory blocks BLK1 to BLKi. The peripheral circuit structure PC may be disposed between the substrate SUB and the memory blocks BLK1 to BLKi.

Each of the memory blocks BLK1 to BLKi may include a source structure, bit lines, cell strings electrically connected to the source structure and the bit lines, word lines electrically connected to the cell strings, and select lines electrically connected to the cell strings. Each of the cell strings may include memory cells and select transistors which are connected in series by a cell plug. Each of the select lines may be used as a gate electrode of a select transistor corresponding thereto, and each of the word lines may be used as a gate electrode of a memory cell corresponding thereto.

In an embodiment, the substrate SUB, the peripheral circuit structure PC, and the memory blocks BLK1 to BLKi may be stacked in the reverse order of the order illustrated in FIG. 2. For example, the peripheral circuit structure PC may be disposed on the memory blocks BLK1 to BLKi.

In an embodiment, unlike the configuration illustrated in FIG. 2, the peripheral circuit structure PC may be disposed in partial areas of the substrate SUB that do not overlap with the memory blocks BLK1 to BLKi. For example, the peripheral circuit structure PC and the memory blocks BLK1 to BLKi may be disposed in respective areas of the substrate SUB that do not overlap with each other.

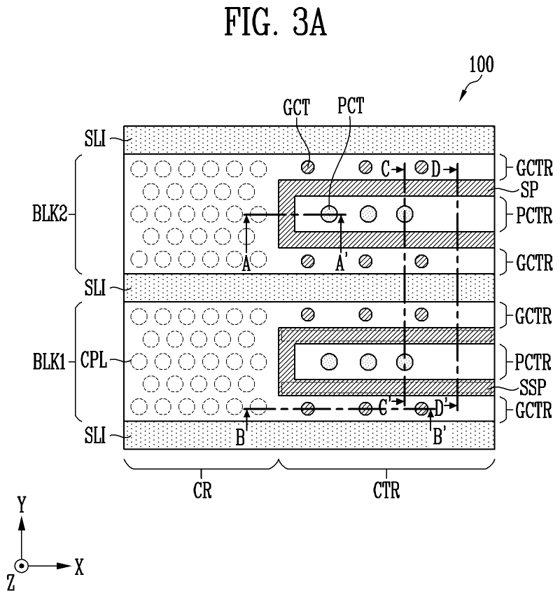

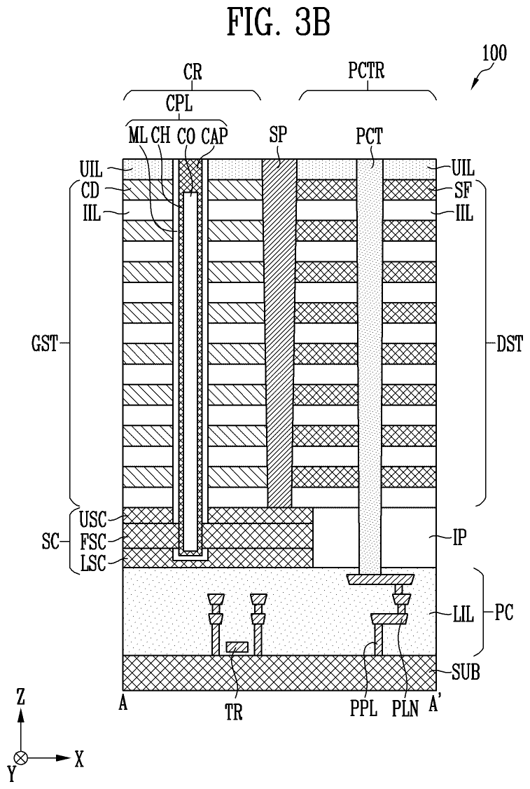

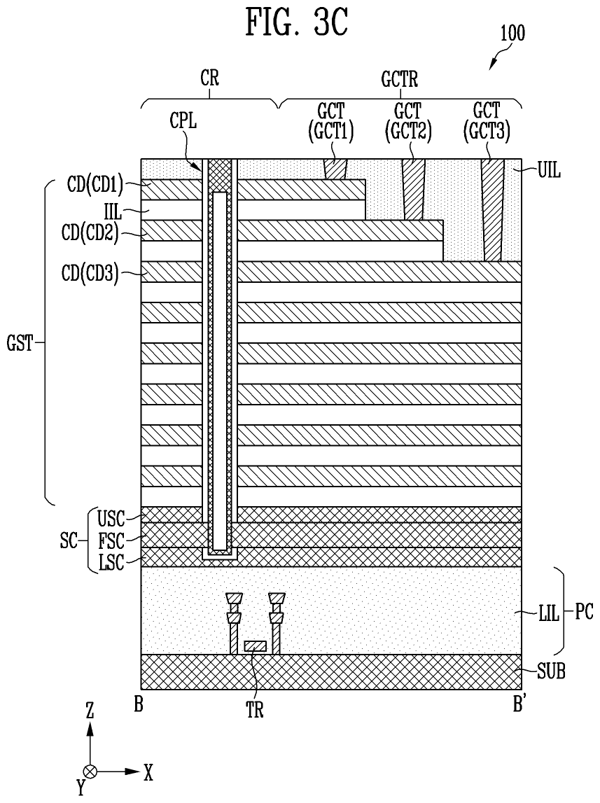

FIGS. 3A to 3C are diagrams illustrating a cell area and a contact area according to an embodiment of the present disclosure. FIG. 3A is a diagram illustrating the layout of a memory device according to an embodiment of the present disclosure. FIG. 3B is a sectional view taken along line A-A′ of FIG. 3A. FIG. 3C is a sectional view taken along line B-B′ of FIG. 3A.

Referring to FIG. 3A, the memory device 100 may include slits SLI. Each of the slits SLI may extend in the X direction. The slits SLI may be spaced apart from each other in the Y direction. The slits SLI may insulate the memory blocks (e.g. memory blocks BLK1 to BLKi in FIG. 2) from each other. For example, the first memory block BLK1 may be separated from the second memory block BLK2 by a slit SLI.

The memory device 100 may include a cell area CR and a contact area CTR. The contact area CTR may be located in the X direction from the cell area CR. The contact area CTR may extend from the cell area CR in the X direction. Cell plugs CPL may be located in the cell area CR.

A support pattern SP may be disposed in the contact area CTR. The support pattern SP may separate the contact area CTR into a first contact area GCTR and a second contact area PCTR. The support pattern SP may enclose at least three surfaces (e.g. surfaces in the Y direction, in a direction opposite to the Y direction, and in a direction opposite to the X direction) of the second contact area PCTR. For example, the support pattern SP may include sub-support patterns SSP each extending in the X direction. The sub-support patterns SSP may contact both sides of the second contact area PCTR in the Y direction. The first contact area GCTR may be located in the Y direction and in the direction opposite to the Y direction of the second contact area PCTR with the support pattern SP interposed therebetween. That is, the support pattern SP may be disposed between the second contact area PCTR and the first contact area GCTR. Further, the support pattern SP may be disposed between the second contact area PCTR and the cell area CR.

The first contact area GCTR may be coupled to the cell area CR. The first contact area GCTR may extend from the cell area CR. The first contact area GCTR may be electrically connected to the cell area CR. First contacts GCT may be located in the first contact area GCTR. The first contacts GCT may be coupled to gate lines (e.g. the drain select line DSL, the word line WL, and the source select line SSL of FIG. 1), respectively.

The second contact area PCTR may be separated from the cell area CR. The second contact area PCTR may be electrically insulated from the cell area CR and the first contact area GCTR by the support pattern SP. Second contacts PCT may be located in the second contact area PCTR. The second contacts PCT may be coupled to a peripheral circuit structure (e.g. the peripheral circuit structure PC of FIG. 2).

FIG. 3B shows a sectional view taken along line A-A′ of FIG. 3A. Referring to FIG. 3B, the memory device 100 may include a gate stacked body GST and a dummy stacked body DST. The cell area CR of the memory device 100 may include the gate stacked body GST, and the second contact area PCTR may include the dummy stacked body DST. The gate stacked body GST may be located in the cell area CR, and the dummy stacked body DST may be located in the second contact area PCTR. The gate stacked body GST may be spaced apart from the dummy stacked body DST with the support pattern SP interposed therebetween. An upper insulating layer UIL may be disposed on the gate stacked body GST and the dummy stacked body DST. The upper insulating layer UIL may cover the gate stacked body GST and the dummy stacked body DST.

The gate stacked body GST may include conductive layers CD and interlayer insulating layers IIL. Conductive and insulating, as used herein, may refer to electrically conductive and electrically insulating. The conductive layers CD and the interlayer insulating layers IIL may be alternately stacked along the Z direction. The conductive layers CD may be formed of at least one of tungsten (W), cobalt (Co), nickel (Ni), molybdenum (Mo), silicon (Si), or poly-silicon (poly-Si). The interlayer insulating layers IIL may be formed of an oxide layer (e.g. silicon oxide layer). The conductive layers CD may correspond to the gate lines (e.g. the drain select line DSL, word line WL, and source select line SSL of FIG. 1).

The dummy stacked body DST may include sacrificial layers SF and interlayer insulating layers IIL. The sacrificial layers SF and the interlayer insulating layers IIL may be alternately stacked along the Z direction. The sacrificial layers SF may include an insulating material having etch selectivity to the interlayer insulating layers IIL. For example, the interlayer insulating layers IIL may include an oxide layer (e.g. silicon oxide layer), and the sacrificial layers SF may include a nitride layer. The sacrificial layers SF of the dummy stacked body DST may be located at the same level as the conductive layers CD of the gate stacked body GST. The sacrificial layers SF may be spaced apart from the conductive layers CD with the support pattern SP interposed therebetween. The interlayer insulating layers IIL of the dummy stacked body DST may be located at the same level as the interlayer insulating layers IIL of the gate stacked body GST and may both include the same material.

A source structure SC may be disposed under the gate stacked body GST and the dummy stacked body DST. The source structure SC may include an upper source structure USC, an interlayer source structure FSC, and a lower source structure LSC. The interlayer source structure FSC may be disposed on the lower source structure LSC, and the upper source structure USC may be disposed on the interlayer source structure FSC. Each of the upper source structure USC, the interlayer source structure FSC, and the lower source structure LSC may include a semiconductor material such as silicon (Si), germanium (Ge), silicon germanium (SiGe), gallium arsenide (GaAs), indium gallium arsenide (InGaAs), aluminum gallium arsenide (AlGaAs), or a combination thereof. Each of the upper source structure USC, the interlayer source structure FSC, and the lower source structure LSC may include at least one of an n-type impurity and a p-type impurity. For example, at least one of the upper source structure USC, the interlayer source structure FSC, or the lower source structure LSC may be a polysilicon layer doped with n-type impurities.

An insulation pattern IP may be disposed under the dummy stacked body DST. The insulation pattern IP may overlap with at least a portion of the dummy stacked body DST. The insulation pattern IP may be adjacent to a source structure SC. The insulation pattern IP may be located at the same level as the source structure SC. An upper surface of the insulation pattern IP may be located at the same level as an upper surface of the upper source structure USC, and a lower surface of the insulation pattern IP may be located at the same level as a lower surface of the lower source structure LSC. The insulation pattern IP may include an insulating material (e.g. oxide, nitride).

A peripheral circuit structure PC and a substrate SUB may be located under the source structure SC and the insulation pattern IP. The peripheral circuit structure PC may be located on the substrate SUB. The peripheral circuit structure PC may include a transistor TR, a peripheral contact plug PPL, and a peripheral line PLN. The transistor TR, the peripheral contact plug PPL, and the peripheral line PLN may have various patterns depending on the configuration of the peripheral circuit. For example, the number or arrangement positions of the transistor TR, the peripheral contact plug PPL, and the peripheral line PLN may vary. A lower insulating layer LIL may be located between the transistor TR, the peripheral contact plug PPL, and the peripheral line PLN. For example, the transistor TR, the peripheral contact plug PPL, and the peripheral line PLN may be formed in the lower insulating layer LIL.

The cell plug CPL may be formed in the cell area CR. The cell plug CPL may penetrate the gate stacked body GST. The cell plug CPL may extend in the Z direction. Memory cells and select transistors may be formed at points where the cell plug CPL and the conductive layers CD intersect.

The cell plug CPL may include a memory layer ML, a channel layer CH, a core pillar CO, and a capping layer CAP. The memory layer ML may have a cylindrical shape. The memory layer ML may contact the gate stacked body GST. Although not shown in the drawing, the memory layer ML may include a blocking layer, a charge trap layer, and a tunnel insulating layer. The channel layer CH may be formed along an inner wall of the memory layer ML. The core pillar CO may have a cylindrical shape enclosed by the channel layer CH. The capping layer CAP may be coupled to the channel layer CH on the core pillar CO.

The blocking layer and the tunnel insulating layer included in the memory layer ML may be formed of an oxide layer (e.g. silicon oxide layer) or an oxynitride layer (e.g. silicon oxynitride layer) or formed of a combination thereof. The charge trap layer included in the memory layer ML may include a nitride layer or a variable resistance material. The channel layer CH and the capping layer CAP may be formed of an undoped silicon layer or a doped silicon layer. Because the capping layer CAP and the channel layer CH are formed of the same material or the same type of material, a boundary between the two might not be clearly defined. The core pillar CO may be formed of the insulating layer or the conductive layer.

The cell plug CPL may contact the source structure SC. The cell plug CPL may extend through the gate stacked body GST into the source structure SC. The cell plug CPL may penetrate the upper source structure USC and the interlayer source structure FSC, and may extend into the lower source structure LSC. The memory layer ML may be disposed between the channel layer CH and the upper source structure USC, and between the channel layer CH and the lower source structure LSC. The memory layer ML might be absent between the channel layer CH and the interlayer source structure FSC. Therefore, the channel layer CH may directly contact the interlayer source structure FSC.

The second contact PCT may be formed in the second contact area PCTR. The second contact PCT may penetrate the dummy stacked body DST. The second contact PCT may penetrate the sacrificial layers SF and the interlayer insulating layers IIL of the dummy stacked body DST. The second contact PCT may penetrate the insulation pattern IP. The second contact PCT may be coupled to the peripheral circuit structure PC. For example, the second contact PCT may directly contact the peripheral line PLN of the peripheral circuit structure PC. The second contact PCT may be understood as a peripheral circuit coupling contact. The second contact PCT may contain a conductive material.

Referring to FIG. 3C, the configuration described with reference to FIGS. 3A and 3B may be omitted or briefly described. FIG. 3C shows a sectional view taken along line B-B′ of FIG. 3A.

The gate stacked body GST may extend from the cell area CR to the first contact area GCTR. The first contact area GCTR may include the gate stacked body GST. The gate stacked body GST may include a stepped structure arranged along the X direction in the first contact area GCTR. The first contact area GCTR may include a stepped structure arranged along the X direction. For example, the lengths of the conductive layers CD included in the gate stacked body GST in the X direction may be different from each other. In FIG. 3C, starting from a conductive layer CD located at the top among the conductive layers CD included in the gate stacked body GST, they may be sequentially referred to as a first conductive layer CD1, a second conductive layer CD2, and a third conductive layer CD3. The first conductive layer CD1 may have a shorter length in the X direction than the second conductive layer CD2, and the second conductive layer CD2 may have a shorter length in the X direction than the third conductive layer CD3. The second conductive layer CD2 may extend farther in the X direction than the first conductive layer CD1. For example, the second conductive layer CD2 may protrude farther in the X direction than the first conductive layer CD1. The third conductive layer CD3 may extend farther in the X direction than the second conductive layer CD2. For example, the third conductive layer CD3 may protrude farther in the X direction than the second conductive layer CD2. Ends of respective conductive layers CD may be exposed on the gate stacked body GST. For example, the end of the first conductive layer CD1, the end of the second conductive layer CD2, and the end of the third conductive layer CD3 may contact the upper insulating layer UIL. Although not shown in the drawing, additional conductive layers CD disposed under the third conductive layer CD3 may also include a stepped structure arranged along the X direction. In the present disclosure, when the stepped structure is described, a description is focused on the conductive layers CD (or sacrificial layers SF). However, as shown in FIG. 3C, each step may include the conductive layer CD (or the sacrificial layer SF) and the interlayer insulating layer IIL. That is, even if there is no mention that each step included in the stepped structure includes the interlayer insulating layer IIL, each step may be understood as including the interlayer insulating layer IIL.

The first contacts GCT may be formed in the first contact area GCTR. The first contacts GCT may be coupled to the conductive layers CD of the gate stacked body GST, respectively. The first contacts GCT may contact ends of the conductive layers CD. For example, the first contacts GCT1, GCT2, and GCT3 may directly contact the first to third conductive layers CD1, CD2, and CD3, respectively. The first contacts GCT may be understood as a gate line coupling contact. The first contacts GCT may include a conductive material.

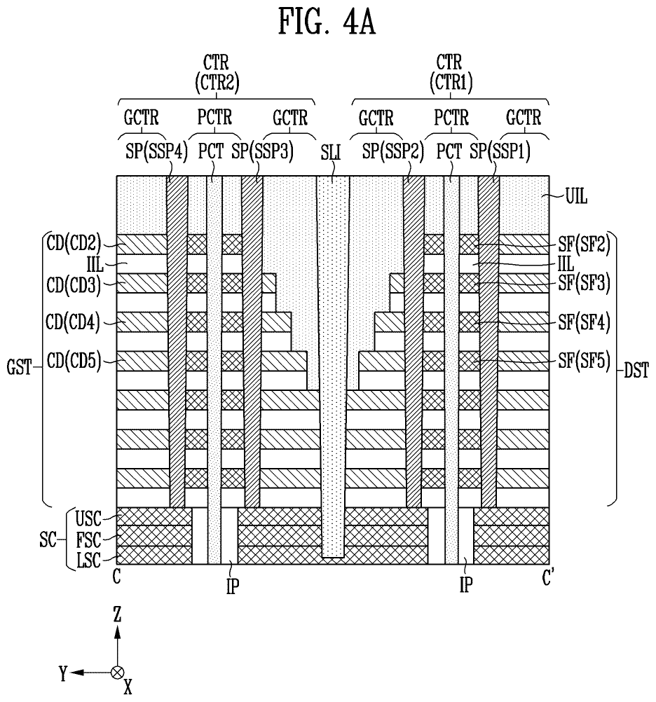

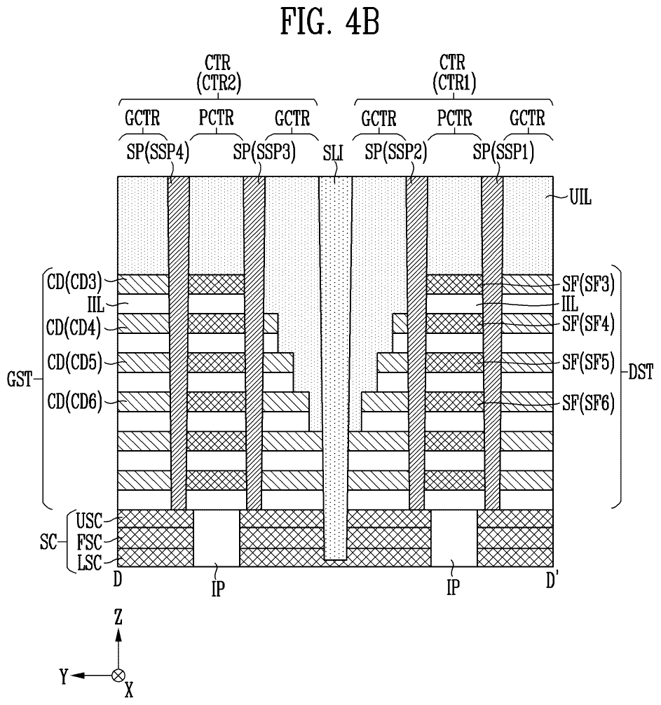

FIGS. 4A and 4B are diagrams illustrating a support pattern that overlaps a stepped structure according to a first embodiment of the present disclosure. FIG. 4A is a sectional view taken along line C-C′ of FIG. 3A. FIG. 4B is a sectional view taken along line D-D′ of FIG. 3A. Among the configurations shown in FIGS. 4A and 4B, the configuration described with reference to FIGS. 3A to 3C may be omitted or briefly described.

Referring to FIGS. 4A and 4B, each of the contact areas CTR may be divided into the first contact area GCTR and the second contact area PCTR by the support pattern SP (e.g. sub-support patterns SSP1 to SSP4). The support pattern SP (e.g. sub-support patterns SSP1 to SSP4) may be disposed between the first contact area GCTR and the second contact area PCTR. The first contact area GCTR and the second contact area PCTR may be spaced apart from each other by the support pattern SP. The first contact area GCTR may be adjacent to the second contact area PCTR with the support pattern SP interposed therebetween. The first contact area GCTR may be located on both sides of the second contact area PCTR. For example, the first contact area GCTR may be located in the Y direction and in the direction opposite to the Y direction of the second contact area PCTR.

The contact areas CTR1 and CTR2 included in different memory blocks (e.g. the first and second memory blocks BLK1 and BLK2 in FIG. 3A) may be separated from each other by the slit SLI. The contact areas CTR1 and CTR2 may be insulated from each other by the slit SLI. The slit SLI may pass through the upper insulating layer UIL and the gate stacked body GST, and extend into the source structure SC. The slit SLI may be formed of a single layer (e.g. a silicon layer, an insulating layer) or a multi-layer (e.g. a conductive layer enclosed by the insulating layer, a silicon layer enclosed by the insulating layer).

Comparing FIGS. 4A and 4B, the contact area CTR may include a stepped structure arranged along the X direction. As described in FIG. 3C, because the third conductive layer CD3 extends farther in the X direction than the second conductive layer CD2, the second conductive layer CD2 shown in FIG. 4A is not shown in FIG. 4B. Likewise, because the third sacrificial layer SF3 extends farther in the X direction than the second sacrificial layer SF2, the second sacrificial layer SF2 shown in FIG. 4A is not shown in FIG. 4B. When describing the stepped structure in the present disclosure, the conductive layer and the sacrificial layer (e.g. the second conductive layer CD2 and the second sacrificial layer SF2) disposed at the same level may be referred to as a stacked layer (e.g. the second stacked layer CD2 and SF2). For example, the length of the third stacked layer CD3 and SF3 in the X direction may be longer than the length of the second stacked layer CD2 and SF2 in the X direction.

Referring to FIGS. 4A and 4B, the contact area CTR may include a stepped structure arranged along the X direction as well as the Y direction. At least some of the stacked layers CD and SF included in the contact area CTR may include a stepped structure arranged along the Y direction. For example, at least some of the stacked layers CD and SF may have different lengths in the Y direction. In the contact area CTR1 on the right side of FIG. 4A, the third stacked layer CD3 and SF3 may extend farther in the Y direction than the second stacked layer CD2 and SF2, a fourth stacked layer CD4 and SF4 may extend farther in the Y direction than the third stacked layer CD3 and SF3, and a fifth stacked layer CD5 and SF5 may extend farther in the Y direction than the fourth stacked layer CD4 and SF4. In the contact area CTR1 on the right side of FIG. 4A, the second stacked layer CD2 and SF2 may have a shorter length in the Y direction than the third stacked layer CD3 and SF3, the third stacked layer CD3 and SF3 may have a shorter length in the Y direction than the fourth stacked layer CD4 and SF4, and the fourth stacked layer CD4 and SF4 may have a shorter length in the Y direction than the fifth stacked layer CD5 and SF5. In the present disclosure, the number of stacked layers CD and SF including the stepped structure arranged in the X direction or the Y direction is not be limited to what is illustrated in FIGS. 4A and 4B. For example, in FIG. 4A, four stacked layers are shown as having a stepped structure in the Y direction. However, five or more stacked layers may have a stepped structure in the Y direction.

The Y-direction stepped structures formed in the contact area CTR may have a symmetrical shape with respect to the slit SLI. For example, in the contact area CTR2 on the left side of FIG. 4A, the third stacked layer CD3 and SF3 may extend farther in the direction opposite to the Y direction than the second stacked layer CD2 and SF2, the fourth stacked layer CD4 and SF4 may extend farther in the direction opposite to the Y direction than the third stacked layer CD3 and SF3, and the fifth stacked layer CD5 and SF5 may extend farther in the direction opposite to the Y direction than the fourth stacked layer CD4 and SF4. In the present disclosure, the specific shape of the stepped structure arranged in the X direction or the Y direction might not be limited to that of FIGS. 4A and 4B. For example, in FIG. 4A, the Y-direction stepped structures are shown as having a symmetrical shape with respect to the slit SLI. However, the Y-direction stepped structures may have an asymmetrical shape with respect to the slit SLI, or may be formed only in one contact area CTR1 or CTR2 with respect to the slit SLI.

The upper insulating layer UIL may cover the gate stacked body GST and the dummy stacked body DST. Ends of the stacked layers CD and SF may contact the upper insulating layer UIL. For example, the upper insulating layer UIL may contact upper and side surfaces of the end of each of the stacked layers CD and SF forming the stepped structure.

Referring to FIGS. 4A and 4B, at least a portion of the support pattern SP may overlap at least a portion of the stepped structure arranged along the Y direction. Any one of sub-support patterns SSP1 and SSP2 included in the contact area CTR1 on the right side of FIG. 4A may overlap at least a portion of the stepped structure in the Y direction. Further, any one of sub-support patterns SSP3 and SSP4 included in the contact area CTR2 on the left side of FIG. 4A may overlap at least a portion of the stepped structure in the Y direction. For example, the second sub-support pattern SSP2 and the third sub-support pattern SSP3 may overlap at least a portion of the stepped structure in the Y direction.

Further, referring to FIGS. 4A and 4B, the second contact area PCTR might not overlap the stepped structure arranged along the Y direction. For example, in the right contact area CTR1 of FIG. 4A, the second contact area PCTR does not overlap the stepped structure in the Y direction. Further, in the left contact area CTR2 of FIG. 4A, the second contact area PCTR does not overlap the stepped structure in the Y direction.

Referring to the contact area CTR1 on the right side of FIG. 4A, in order for the stepped structure arranged along the Y direction to overlap the second sub-support pattern SSP2 and not to overlap the second contact area PCTR, the second sub-support pattern SSP2 may be disposed to overlap a point where the stepped structure arranged along the Y direction starts. The point where the stepped structure arranged along the Y direction starts may be a point where an end of the stacked layer (e.g. the second stacked layer CD2 and SF2 in FIG. 4A) located at the top in a specific cross-section is located. Thus, in FIG. 4A, the second sub-support pattern SSP2 may overlap the end of the second stacked layer CD2 and SF2. Further, in FIG. 4B, the second sub-support pattern SSP2 may overlap the end of the third stacked layer CD3 and SF3.

Referring to FIGS. 4A and 4B, the first contact area GCTR may overlap another portion of the stepped structure arranged along the Y direction. Any one of the first contact areas GCTR included in the contact area CTR1 on the right side of FIG. 4A may overlap at least a portion of the stepped structure in the Y direction. Further, any one of the first contact areas GCTR included in the contact area CTR2 on the left side of FIG. 4A may overlap at least a portion of the stepped structure in the Y direction. For example, the first contact areas GCTR disposed adjacent to the slit SLI shown in FIG. 4A may overlap at least a portion of the stepped structure in the Y direction.

At least some of the conductive layers CD included in the first contact area GCTR may have different lengths in the Y direction. For example, referring to FIG. 4A, in the first contact areas GCTR adjacent to the slit SLI, the second to fifth conductive layers CD2 to CD5 may have different lengths in the Y direction. Further, referring to FIG. 4B, in the first contact areas GCTR adjacent to the slit SLI, the third to sixth conductive layers CD3 to CD6 may have different lengths in the Y direction.

The sacrificial layers SF included in the second contact area PCTR may have the same length in the Y direction. For instance, referring to FIG. 4A, the second to fifth sacrificial layers SF2 to SF5 and the sacrificial layers SF located under the fifth sacrificial layer SF5 may have the same length in the Y direction. Further, referring to FIG. 4B, the third to sixth sacrificial layers SF3 to SF6 and the sacrificial layers SF located under the sixth sacrificial layer SF6 may have the same length in the Y direction.

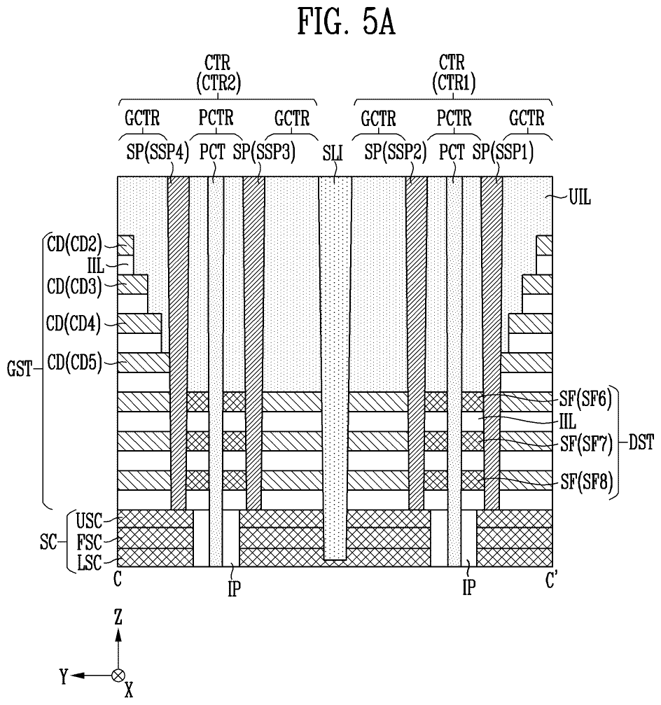

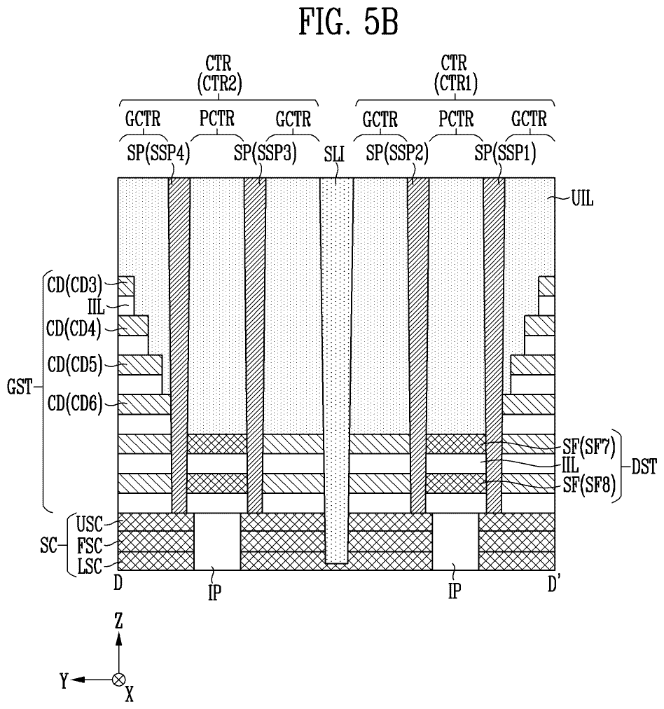

FIGS. 5A and 5B are diagrams illustrating a support pattern that overlaps a stepped structure according to a second embodiment of the present disclosure. FIG. 5A is a sectional view taken along line C-C′ of FIG. 3A. FIG. 5B is a sectional view taken along line D-D′ of FIG. 3A. Among the configurations shown in FIGS. 5A and 5B, the configuration described with reference to FIGS. 3A, 3B, 3C, 4A, and 4B may be omitted or briefly described.

Comparing FIGS. 5A and 5B, the contact area CTR may include a stepped structure arranged along the X direction. As described in FIG. 3C, because the third conductive layer CD3 extends farther in the X direction than the second conductive layer CD2, the second conductive layer CD2 shown in FIG. 5A is not shown in FIG. 5B.

Referring to FIGS. 5A and 5B, the contact area CTR may include a stepped structure arranged along the Y direction. At least some of the conductive layers CD included in the contact area CTR may include a stepped structure arranged along the Y direction. For example, at least some of the conductive layers CD may have different lengths in the Y direction. In the contact area CTR1 on the right side of FIG. 5A, the third conductive layer CD3 may extend farther in the Y direction than the second conductive layer CD2, the fourth conductive layer CD4 may extend farther in the Y direction than the third conductive layer CD3, and the fifth conductive layer CD5 may extend farther in the Y direction than the fourth conductive layer CD4. In the contact area CTR1 on the right side of FIG. 5A, the second conductive layer CD2 may have a shorter length in the Y direction than the third conductive layer CD3, the third conductive layer CD3 may have a shorter length in the Y direction than the fourth conductive layer CD4, and the fourth conductive layer CD4 may have a shorter length in the Y direction than the fifth conductive layer CD5.

The Y-direction stepped structures formed in the contact area CTR may have a symmetrical shape with respect to the slit SLI. For example, in the contact area CTR2 on the left side of FIG. 5A, the third conductive layer CD3 may extend farther in the direction opposite to the Y direction than the second conductive layer CD2, the fourth conductive layer CD4 may extend farther in the direction opposite to the Y direction than the third conductive layer CD3, and the fifth conductive layer CD5 may extend farther in the direction opposite to the Y direction than the fourth conductive layer CD4.

The upper insulating layer UIL may cover the gate stacked body GST and the dummy stacked body DST. Ends of the stacked layers CD and SF may contact the upper insulating layer UIL. For example, the upper insulating layer UIL may contact upper and side surfaces of the end of each of the conductive layers CD forming the stepped structure.

Referring to FIGS. 5A and 5B, at least a portion of the support pattern SP may overlap at least a portion of the stepped structure arranged along the Y direction. Any one of sub-support patterns SSP1 and SSP2 included in the contact area CTR1 on the right side of FIG. 5A may overlap at least a portion of the stepped structure in the Y direction. Further, any one of sub-support patterns SSP3 and SSP4 included in the contact area CTR2 on the left side of FIG. 5A may overlap at least a portion of the stepped structure in the Y direction. For example, the first sub-support pattern SSP1 and the fourth sub-support pattern SSP4 may overlap at least a portion of the stepped structure in the Y direction.

Further, referring to FIGS. 5A and 5B, the second contact area PCTR might not overlap the stepped structure arranged along the Y direction. For example, in the right contact area CTR1 of FIG. 5A, the second contact area PCTR does not overlap the stepped structure in the Y direction. Further, in the left contact area CTR2 of FIG. 5A, the second contact area PCTR does not overlap the stepped structure in the Y direction.

Referring to the contact area CTR1 on the right side of FIG. 5A, in order for the stepped structure arranged along the Y direction to overlap the first sub-support pattern SSP1 and not to overlap the second contact area PCTR, the first sub-support pattern SSP1 may be disposed to overlap a point where the stepped structure arranged along the Y direction ends. Thus, in FIG. 5A, the first sub-support pattern SSP1 may overlap the end of the fifth conductive layer CD5. Further, in FIG. 5B, the first sub-support pattern SSP1 may overlap the end of the sixth conductive layer CD6.

Referring to FIGS. 5A and 5B, the first contact area GCTR may overlap another portion of the stepped structure arranged along the Y direction. Any one of the first contact areas GCTR included in the contact area CTR1 on the right side of FIG. 5A may overlap at least a portion of the stepped structure in the Y direction. Further, any one of the first contact areas GCTR included in the contact area CTR2 on the left side of FIG. 5A may overlap at least a portion of the stepped structure in the Y direction. For example, the first contact areas GCTR disposed farther from the slit SLI shown in FIG. 5A may overlap at least a portion of the stepped structure in the Y direction.

At least some of the conductive layers CD included in the first contact area GCTR may have different lengths in the Y direction. For example, referring to FIG. 5A, in the first contact areas GCTR disposed farther from the slit SLI, the second to fifth conductive layers CD2 to CD5 may have different lengths in the Y direction. Further, referring to FIG. 5B, in the first contact areas GCTR disposed farther from the slit SLI, the third to sixth conductive layers CD3 to CD6 may have different lengths in the Y direction.

The sacrificial layers SF included in the second contact area PCTR may have the same length in the Y direction. For instance, referring to FIG. 5A, the sixth to eighth sacrificial layers SF6 to SF8 may have the same length in the Y direction. Further, referring to FIG. 5B, the seventh and eighth sacrificial layers SF7 and SF8 may have the same length in the Y direction.

According to the present disclosure, by adjusting a relative position between the support pattern SP and the stacked body (e.g. the gate stacked body GST, the dummy stacked body DST) in the contact area CTR, the stability of the stacked body can be improved or ensured. An arrangement is made such that some of the sub-support patterns SSP overlap the stepped structure arranged along the Y direction in the contact area CTR and the second contact area PCTR does not overlap therewith, thereby improving or securing the structural stability of the second contact area PCTR. For example, unlike the present disclosure, when a slope occurs between the dummy stacked body DST and the upper insulating layer UIL in the second contact area PCTR, defects such as the bending of the second contact area PCTR may occur due to a difference in material properties between different materials (e.g. oxide and nitride). However, as in the present disclosure, when the slope between the dummy stacked body DST and the upper insulating layer UIL is eliminated in the second contact area PCTR, it is possible to mitigate or prevent the second contact area PCTR from being bent in the Y direction.

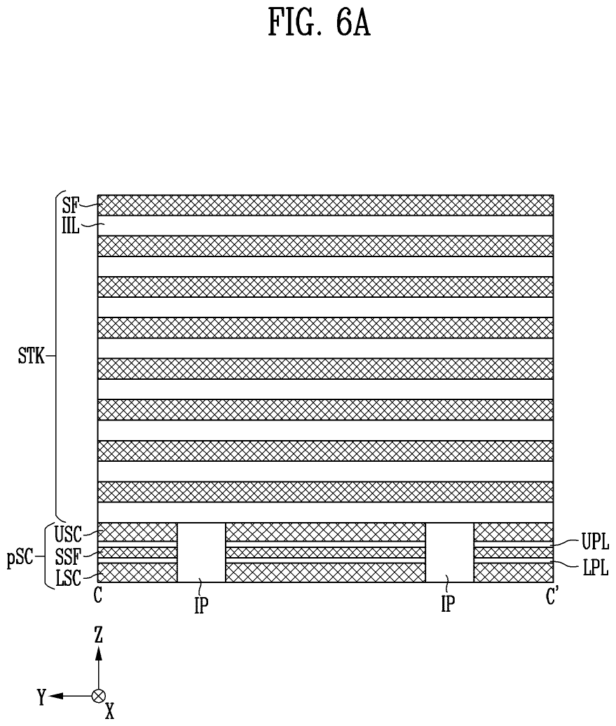

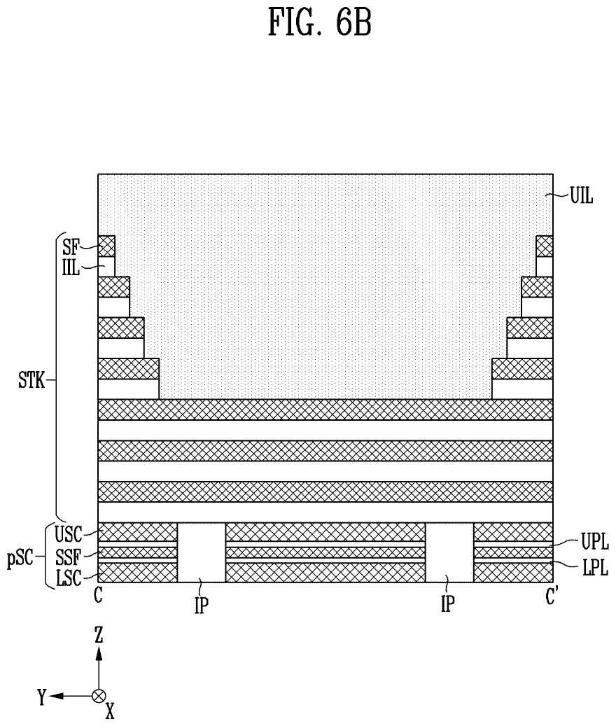

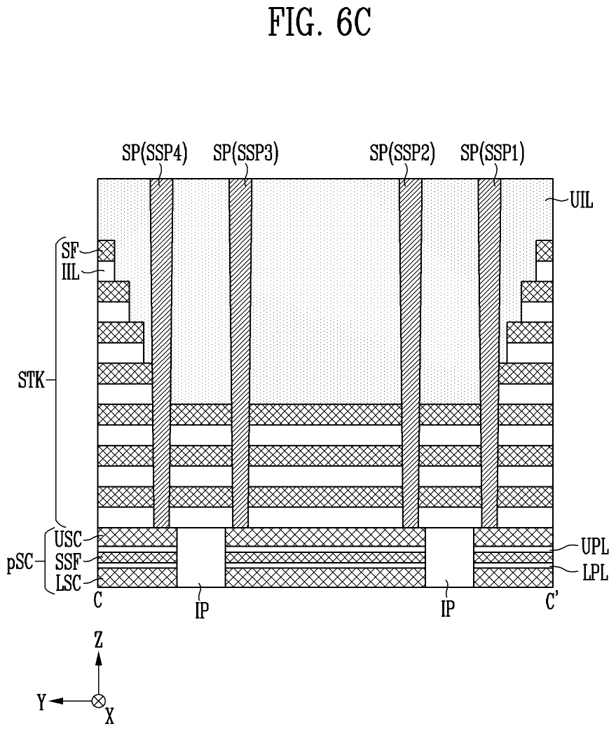

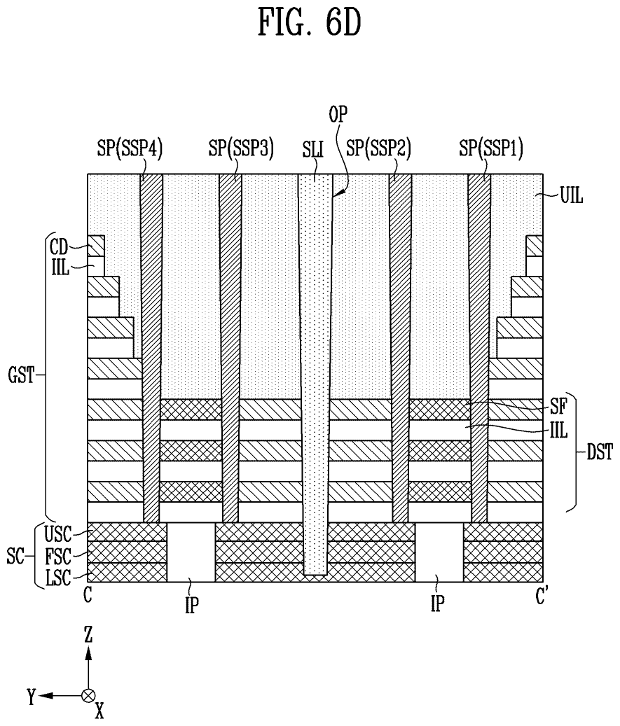

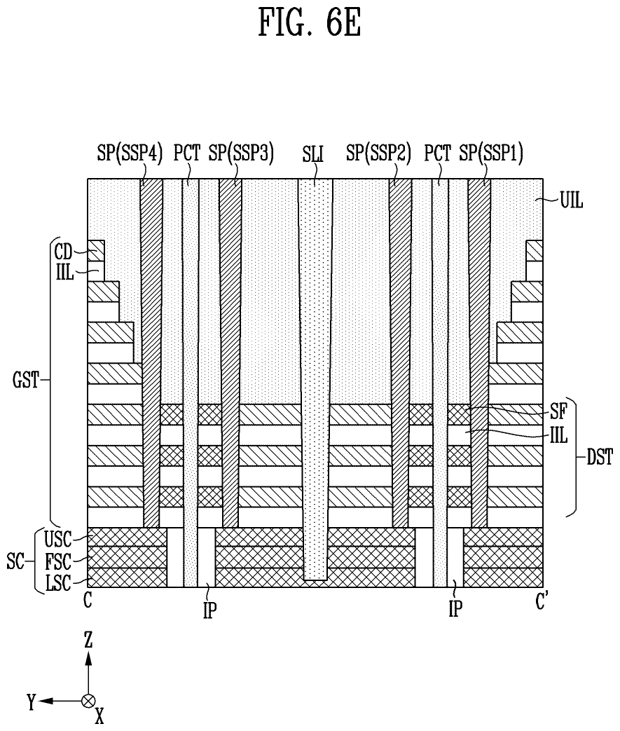

FIGS. 6A to 6E are diagrams illustrating a method of manufacturing a memory device according to an embodiment of the present disclosure. FIGS. 6A to 6E are sectional views taken along line C-C′ of FIG. 3A. Although FIGS. 6A to 6E are described based on the second embodiment among the first embodiment of FIG. 4A and the second embodiment of FIG. 5A, the following description may also be applied to the first embodiment except for the relative position between the stepped structure and the sub-support patterns SSP.

Referring to FIG. 6A, a lower source structure LSC, a source sacrificial layer SSF, and an upper source structure USC may be sequentially stacked on a substrate (e.g. the substrate SUB of FIGS. 3B and 3C) including a peripheral circuit (e.g. the peripheral circuit structure PC of FIGS. 3B and 3C) or a sacrificial substrate (not shown) to form a preliminary source structure pSC. The preliminary source structure pSC may further include at least one of a lower protective layer LPL between the lower source structure LSC and the source sacrificial layer SSF and an upper protective layer UPL disposed between the source sacrificial layer SSF and the upper source structure USC. The preliminary source structure pSC may include an upper surface extending in the X direction and the Y direction that intersect each other.

Subsequently, an insulation pattern IP penetrating the preliminary source structure pSC may be formed. The insulation pattern IP may extend along the X direction. For example, the insulation pattern IP may be formed at a position overlapping at least a portion of the second contact area PCTR shown in FIG. 3A.

Subsequently, a preliminary stacked body STK may be formed on the preliminary source structure pSC and the insulation pattern IP. The preliminary stacked body STK may include sacrificial layers SF and interlayer insulating layers IIL that are alternately stacked in the Z direction. For instance, after the interlayer insulating layer IIL is stacked on the insulation pattern IP and the preliminary source structure pSC, the sacrificial layer SF may be stacked on the interlayer insulating layer IIL. The sacrificial layers SF may have etch selectivity relative to the interlayer insulating layers IIL. In an embodiment, the interlayer insulating layers IIL may contain an oxide such as a silicon oxide layer, and the sacrificial layers SF may contain a nitride such as a silicon nitride layer.

Subsequently, although not shown in the drawing, cell plugs (e.g. the cell plugs CPL of FIGS. 3A to 3C) penetrating the preliminary stacked body STK may be formed. For example, the cell plugs may be formed in a cell area (e.g. the cell area CR of FIG. 3A) of the preliminary stacked body STK. The cell plugs may extend through the preliminary stacked body STK into the preliminary source structure pSC. For example, the cell plugs may penetrate the upper source structure USC and the source sacrificial layer SSF.

Referring to FIG. 6B, a stepped structure arranged along the X direction and the Y direction may be formed in a contact area (e.g. the contact area CTR of FIG. 3A) of the preliminary stacked body STK. A portion of the preliminary stacked body STK may be etched to form the stepped structure arranged along the X direction and the Y direction. In an embodiment, the stepped structure may be formed so that the interlayer insulating layer IIL and the sacrificial layer SF stacked adjacent to each other form one step. For example, in FIG. 6B, any one sacrificial layer SF and the interlayer insulating layer IIL contacting the lower surface of the sacrificial layer SF may correspond to one step. Although FIG. 6B shows only a stepped structure arranged along the Y direction among stepped structures included in the preliminary stacked body STK, the preliminary stacked body STK may also include a stepped structure arranged along the X direction as shown in FIGS. 3C, 4A, 4B, 5A, and 5B.

Subsequently, an upper insulating layer UIL covering the preliminary stacked body STK may be formed. The upper insulating layer UIL may cover the stepped structure of the preliminary stacked body STK. For example, the upper insulating layer UIL may cover the stepped structures in the X direction and the Y direction, included in the preliminary stacked body STK. Thus, the upper insulating layer UIL may directly contact ends (e.g. the ends of the sacrificial layers SF) of each step included in the preliminary stacked body STK.

Referring to FIG. 6C, a support pattern SP may be formed to penetrate a contact area (e.g. the contact area CTR of FIG. 3A) of the preliminary stacked body STK. The support pattern SP may include sub-support patterns SSP1 to SSP4 each extending in the X direction. At least one of the sub-support patterns SSP1 to SSP4 may overlap at least a portion of the stepped structure along the Y direction. For example, the first sub-support pattern SSP1 and the fourth sub-support pattern SSP4 may overlap ends of the sacrificial layers SF in the Y direction. Further, the sub-support patterns SSP1 to SSP4 may be formed to prevent the stepped structure along the Y direction from being located between the sub-support patterns SSP1 and SSP2 or SSP3 and SSP4 included in one support pattern SP. For example, the ends of the sacrificial layers SF in the Y direction might not be located between the first sub-support pattern SSP1 and the second sub-support pattern SSP2. Further, the ends of the sacrificial layers SF in the Y direction might not be located between the third sub-support pattern SSP3 and the fourth sub-support pattern SSP4. However, the stepped structure along the X direction may also be located between the sub-support patterns SSP1 and SSP2 or SSP3 and SSP4 included in one support pattern SP.

The support pattern SP may be formed in an area of the preliminary stacked body STK, so that the contact area (e.g. the contact area CTR of FIG. 3A) of the preliminary stacked body STK may be divided into a first contact area (e.g. the first contact area GCTR of FIG. 3A) and a second contact area (e.g. the second contact area PCTR of FIG. 3A). For example, an area between the first and second sub-support patterns SSP1 and SSP2 and an area between the third and fourth sub-support patterns SSP3 and SSP4 may become a second contact area (e.g. the second contact area PCTR of FIG. 3A). Further, an area other than the second contact area (e.g. the second contact area PCTR of FIG. 3A) may become the first contact area (e.g. the first contact area GCTR of FIG. 3A). The second contact area (e.g. the second contact area PCTR of FIG. 3A) may be formed to be enclosed by the support pattern SP.

Referring to FIG. 6D, an opening OP may be formed to pass through the preliminary stacked body STK. A side surface of the source sacrificial layer SSF may be exposed through the opening OP. The source sacrificial layer SSF may be removed through the opening OP. Although not shown in the drawing, a portion of a memory layer (e.g. the memory layer ML of FIG. 3B) of the cell plug (e.g. the cell plug CPL of FIG. 3B) may be removed through the opening OP. While a portion of the memory layer ML is removed through the opening OP, an upper protective layer UPL and a lower protective layer LPL may be removed. Subsequently, an interlayer source structure FSC may be filled between the upper source structure USC and the lower source structure LSC through the opening OP. As the interlayer source structure FSC is filled, the source structure SC including the upper source structure USC, the interlayer source structure FSC, and the lower source structure LSC may be formed.

Further, some of the sacrificial layers SF may be exposed through the opening OP. The sacrificial layers SF exposed through the opening OP may be removed. For example, the sacrificial layers SF located in the cell area CR and the first contact area GCTR of FIG. 3A may be removed. The conductive layers CD may be filled in spaces from which the sacrificial layers SF are removed through the opening OP.

While some of the sacrificial layers SF are removed, other sacrificial layers SF that are not exposed through the opening OP may remain without being removed. For example, the sacrificial layers SF located in the second contact area PCTR of FIG. 3A might not be removed because they are enclosed by the support pattern SP. The sacrificial layers disposed between the first sub-support pattern SSP1 and the second sub-support pattern SSP2 might not be removed. Further, the sacrificial layers disposed between the third sub-support pattern SSP3 and the fourth sub-support pattern SSP4 might not be removed.

Therefore, a portion of the preliminary stacked body STK may become a gate stacked body GST including the conductive layers CD and the interlayer insulating layers IIL, while another portion of the preliminary stacked body STK may become a dummy stacked body DST including the sacrificial layers SF and the interlayer insulating layers IIL. Referring to FIG. 6D, the dummy stacked body DST might not include a stepped structure arranged along the Y direction, and the gate stacked body GST may include a stepped structure arranged along the Y direction. For example, because the support pattern SP is formed so that an area (e.g. the second contact area PCTR of FIG. 3A) enclosed by each support pattern SP does not overlap the stepped structure along the Y direction, the dummy stacked body DST might not include the stepped structure arranged along the Y direction. Further, because the support pattern SP is formed so that an area (e.g. the first contact area GCTR of FIG. 3A) that is not enclosed by each support pattern SP overlaps the stepped structure along the Y direction, the gate stacked body GST may include the stepped structure arranged along the Y direction. Although not shown in the drawing, both the gate stacked body GST and the dummy stacked body DST may include the stepped structure along the X direction.

After some of the sacrificial layers SF are replaced with the conductive layers CD through the opening OP, a slit SLI may be formed in the opening OP. The slit SLI may contain at least one material filled in the opening OP.

Referring to FIG. 6E, second contacts PCT may be formed to penetrate the dummy stacked body DST. The second contacts PCT may penetrate the upper insulating layer UIL, the dummy stacked body DST, and the insulation pattern IP. The second contacts PCT may directly contact a peripheral circuit structure (e.g. the peripheral circuit structure PC of FIGS. 3B and 3C) located under the insulation pattern IP.

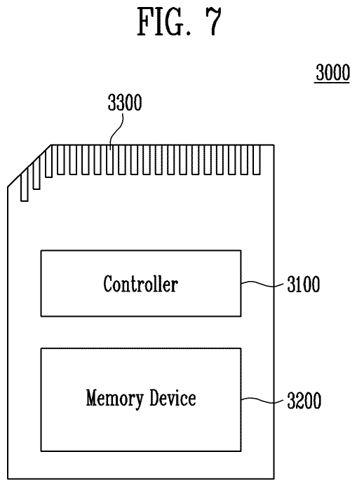

FIG. 7 is a diagram illustrating a memory card system to which a memory device according to an embodiment of the present disclosure is applied.

Referring to FIG. 7, a memory card system 3000 may include a controller 3100, a memory device 3200, and a connector 3300.

The controller 3100 may be coupled to the memory device 3200. The controller 3100 may access the memory device 3200. For example, the controller 3100 may control a program operation, a read operation, or an erase operation of the memory device 3200, or may control a background operation of the memory device 3200. The controller 3100 may provide an interface between the memory device 3200 and a host. The controller 3100 may run firmware for controlling the memory device 3200. In an example, the controller 3100 may include components, such as random-access memory (RAM), a processor, a host interface, a memory interface, and an error corrector.

The controller 3100 may communicate with an external device through the connector 3300. The controller 3100 may communicate with an external device (e.g., a host) based on a specific communication standard. For example, the controller 3100 may communicate with the external device through at least one of various communication standards such as universal serial bus (USB), multimedia card (MMC), embedded MMC (eMMC), peripheral component interconnection (PCI), PCI-express (PCI-E), advanced technology attachment (ATA) protocol, serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, or nonvolatile memory express (NVMe). For example, the connector 3300 may be defined by at least one of the above-described various communication standards.

The memory device 3200 may include a plurality of memory cells and may be configured in the same manner as the memory device 100 illustrated in FIG. 1.

The controller 3100 and the memory device 3200 may be integrated into a single semiconductor device to form a memory card. For example, the controller 3100 and the memory device 3200 may be integrated into a single semiconductor device, and may then form a memory card such as a personal computer memory card international association (PCMCIA) card, a compact flash card (CF), a smart media card (SM or SMC), a memory stick, a multimedia card (MMC, RS-MMC, MMCmicro or eMMC), an SD card (SD, miniSD, microSD, or SDHC), or a universal flash storage (UFS).

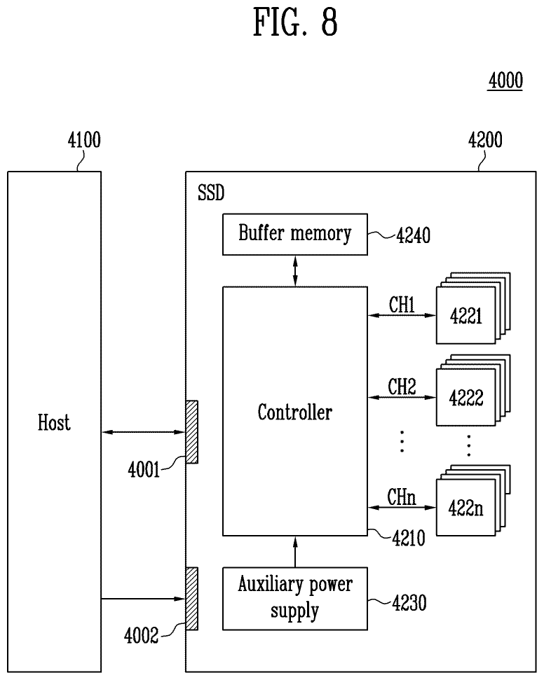

FIG. 8 is a diagram illustrating a solid-state drive (SSD) system to which a memory device according to the present disclosure is applied.

Referring to FIG. 8, an SSD system 4000 may include a host 4100 and an SSD 4200. The SSD 4200 may exchange signals with the host 4100 through a signal connector 4001 and may receive power through a power connector 4002. The SSD 4200 may include a controller 4210, a plurality of memory devices 4221 to 422n, an auxiliary power supply 4230, and buffer memory 4240.

The controller 4210 may control the plurality of memory devices 4221 to 422n in response to signals received from the host 4100. For example, the received signals may be signals based on the interfaces of the host 4100 and the SSD 4200. For example, the signals may be defined by at least one of various interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, or nonvolatile memory express (NVMe).

Each of the plurality of memory devices 4221 to 422n may include a plurality of memory cells configured to store data. Each of the memory devices 4221 to 422n may be configured in the same manner as the memory device 100 illustrated in FIG. 1. The plurality of memory devices 4221 to 422n may communicate with the controller 4210 through channels CH1 to CHn.

The auxiliary power supply 4230 may be coupled to the host 4100 through the power connector 4002. The auxiliary power supply 4230 may be supplied with a supply voltage from the host 4100 and may be charged. The auxiliary power supply 4230 may provide the supply voltage of the SSD 4200 when the supply of power from the host 4100 is not smoothly performed. For example, the auxiliary power supply 4230 may be located inside the SSD 4200 or located outside the SSD 4200. For example, the auxiliary power supply 4230 may be located on a main board and may provide auxiliary power to the SSD 4200.

The buffer memory 4240 may function as buffer memory of the SSD 4200. For example, the buffer memory 4240 may temporarily store data received from the host 4100 or data received from the plurality of memory devices 4221 to 422n, or may temporarily store metadata (e.g., mapping tables) of the memory devices 4221 to 422n. The buffer memory 4240 may include volatile memory, such as dynamic random-access memory (DRAM), synchronous DRAM (SDRAM), double data rate (DDR) SDRAM, and low power DDR (LPDDR) SDRAM, or nonvolatile memory, such as ferroelectric RAM (FRAM), resistive RAM (ReRAM), spin transfer torque magnetic RAM (STT-MRAM), and phase-change RAM (PRAM).

According to the present disclosure, the stability of a stacked body can be improved or ensured by adjusting the positions of a stepped structure and a support pattern of the stacked body in a contact area.

What is claimed is:

1. A memory device comprising:
a cell area;
a contact area extending from the cell area in a first direction, the contact area including a stepped structure arranged along a second direction that intersects the first direction; and
a support pattern separating the contact area into a first contact area coupled to the cell area and a second contact area separated from the cell area by the support pattern,
wherein:
the support pattern comprises sub-support patterns extending in the first direction and contacting both sides of the second contact area,
at least one of the sub-support patterns overlaps at least a first portion of the stepped structure, and
the second contact area does not overlap with the stepped structure.

2. The memory device according to claim 1, wherein the contact area further comprises a stepped structure arranged along the first direction.

3. The memory device according to claim 1, wherein each of the cell area and the first contact area comprises:
a gate stacked body including conductive layers and interlayer insulating layers which are alternately stacked; and
a source structure disposed under the gate stacked body.

4. The memory device according to claim 3, further comprising:
a cell plug penetrating the gate stacked body in the cell area, the cell plug contacting the source structure.

5. The memory device according to claim 3, further comprising:
at least one first contact coupled to at least one of the conductive layers in the first contact area.

6. The memory device according to claim 1, wherein the second contact area comprises:
a dummy stacked body including sacrificial layers and interlayer insulating layers which are alternately stacked;
an insulation pattern disposed under the dummy stacked body; and
a peripheral circuit structure disposed under the insulation pattern.

7. The memory device according to claim 6, further comprising:
a second contact penetrating the dummy stacked body and the insulation pattern, the second contact coupled to the peripheral circuit structure.

8. The memory device according to claim 1, wherein the first contact area overlaps a second portion of the stepped structure.

9. The memory device according to claim 1, wherein the first contact area is located in the second direction and in a direction opposite to the second direction from the second contact area.

10. The memory device according to claim 1, wherein widths of at least some of the conductive layers included in the first contact area in the second direction are different from each other.

11. The memory device according to claim 1, wherein widths of at least some of the sacrificial layers included in the second contact area in the second direction are the same.

12. A method of manufacturing a memory device comprising:
forming a preliminary stacked body including alternately stacked first and second material layers;
forming cell plugs in a cell area of the preliminary stacked body;
forming a stepped structure arranged along a second direction, which intersects a first direction, in a contact area extending from the cell area in the first direction; and
forming a support pattern penetrating the contact area and including sub-support patterns each extending in the first direction, the support pattern separating the contact area into a first contact area and a second contact area enclosed by the support pattern,
wherein, in forming the support pattern, at least one of the sub-support patterns overlaps at least a portion of the stepped structure, and the second contact area does not overlap with the stepped structure.

13. The method according to claim 12, further comprising:
before forming the preliminary stacked body,
forming a preliminary source structure; and
forming an insulation pattern that penetrates the preliminary source structure.

14. The method according to claim 12, further comprising:
after forming the support pattern separating the contact area into the first contact area and the second contact area,
forming a slit passing through the preliminary stacked body;
removing the second material layers of the cell area and the first contact area exposed through the slit; and
filling third material layers in spaces where the second material layers were removed, thereby forming a gate stacked body.

15. The method according to claim 14, wherein, in forming the gate stacked body, the gate stacked body of the first contact area is formed to comprise the stepped structure arranged along the second direction.

16. The method according to claim 14, wherein, in removing the second material layers, the second material layers of the second contact area remain to form a dummy stacked body.

17. The method according to claim 16, wherein, in forming the dummy stacked body, the dummy stacked body of the second contact area is formed not to include the stepped structure arranged along the second direction.

18. The method according to claim 16, further comprising:
after forming the dummy stacked body,
forming a peripheral circuit coupling contact to penetrate the dummy stacked body in the second contact area.

19. The method according to claim 12, wherein, in forming the support pattern, the first contact area is formed to overlap the stepped structure.
